(19) United States
(12) Patent Application Publication
(10) Pub. No.: US 2018/0047435 A1
(43) Pub. Date: Feb. 15, 2018

(54) SEMICONDUCTOR DEVICE

(71) Applicant: SK hynix Inc., Icheon-si Gyeonggi-do (KR)

(72) Inventor: Young Mok JUNG, Icheon-si Gyeonggi-do (KR)

(73) Assignee: SK hynix Inc., Icheon-si Gyeonggi-do (KR)

(21) Appl. No.: 15/481,696

(22) Filed: Apr. 7, 2017

(30) Foreign Application Priority Data
Aug. 12, 2016 (KR) 1020160103294

(51) Int. Cl. G11C 7/22; H04L 7/00; H03L 7/081; H04L 7/033; G11C 7/10; G06F 13/42

(52) U.S. Cl. CPC G11C 7/222; G11C 7/1093; G11C 7/1078; G11C 7/1072; G06F 13/4243; H03L 7/0814; H04L 7/033; H04L 7/0037

(57) ABSTRACT

A semiconductor device may be provided. The semiconductor device may include a signal mixing circuit suitable for generating a strobe signal which toggles in synchronization with a divided clock. The semiconductor device may include a signal transfer circuit suitable for transmitting the strobe signal, and including at least one repeater which amplifies and transmits the strobe signal.

### CROSS-REFERENCE TO RELATED APPLICATION

The present application claims priority under 35 U.S.C. §119(a) to Korean Patent Application No. 10-2016-0103294 filed on Aug. 12, 2016 in the Korean Intellectual Property Office, which is incorporated herein by reference in its entirety.

### BACKGROUND

### 1. Technical Field

Embodiments of the present disclosure may generally relate to a semiconductor device which inputs and outputs data in synchronization with a strobe signal.

### 2. Related Art

In a synchronous semiconductor device, a command and an address are inputted in synchronization with a clock. In a DDR (double data rate) synchronous semiconductor device, a command and an address are inputted in synchronization with the rising edge and the falling edge of a clock. In an SDR (single data rate) synchronous semiconductor device, a command and an address are inputted in synchronization with the rising edge of a clock.

### SUMMARY

In an embodiment, a semiconductor device may be provided. The semiconductor device may include a signal mixing circuit suitable for generating a strobe signal which toggles in synchronization with a divided clock. The semiconductor device may include a signal transfer circuit suitable for transmitting the strobe signal, and including at least one repeater which amplifies and transmits the strobe signal.

In an embodiment, a semiconductor device may be provided. The semiconductor device may include a signal mixing circuit configured for generating a strobe signal based on combining a divided clock and a preamble signal during a preamble period. The semiconductor device may include a signal transfer circuit suitable for transmitting the strobe signal, and including at least one repeater which amplifies and transmits the strobe signal.

### BRIEF DESCRIPTION OF THE DRAWINGS

FIG. 1 is a block diagram illustrating a representation of an example of the configuration of a semiconductor device in accordance with an embodiment.

FIG. 2 is a circuit diagram illustrating a representation of an example of the internal configuration of the signal mixing circuit included in the semiconductor device illustrated in FIG. 1.

FIG. 3 is a representation of an example of a timing diagram to assist in the explanation of the operations of the control circuit and the signal mixing circuit included in the semiconductor device illustrated in FIG. 1.

FIG. 4 is a block diagram illustrating a representation of an example of the internal configuration of the first signal transfer circuit included in the semiconductor device illustrated in FIG. 1.

FIG. 5 is a circuit diagram illustrating a representation of an example of the internal configuration of the buffer circuit included in the first signal transfer circuit illustrated in FIG. 4.

FIG. 6 is a representation of an example of a timing diagram to assist in the explanation of the operation of the buffer circuit included in the first signal transfer circuit, illustrated in FIG. 5.

FIG. 7 is a diagram illustrating a representation of an example of the internal configuration of the first internal strobe signal generation circuit included in the semiconductor device illustrated in FIG. 1.

FIG. 8 is a representation of an example of a timing diagram to assist in the explanation of the operation of the first internal strobe signal generation circuit included in the semiconductor device, illustrated in FIG. 7.

FIG. 9 is a diagram illustrating a representation of an example of the configuration of an electronic system to which the semiconductor device illustrated in FIGS. 1 to 8 is applied.

### DETAILED DESCRIPTION

Hereinafter, a semiconductor device will be described below with reference to the accompanying drawings through various examples of embodiments.

Various embodiments may be directed to a semiconductor device which generates a strobe signal by mixing a divided clock and a preamble signal during a preamble period and outputs the strobe signal through a plurality of repeaters to a pad.

According to the embodiments, a strobe signal may be generated by mixing a divided clock and a preamble signal during a preamble period, and the strobe signal may be outputted through a plurality of repeaters to a pad. As a consequence, it may be possible to prevent a mismatch of the divided clock and the preamble signal due to a long transfer path.

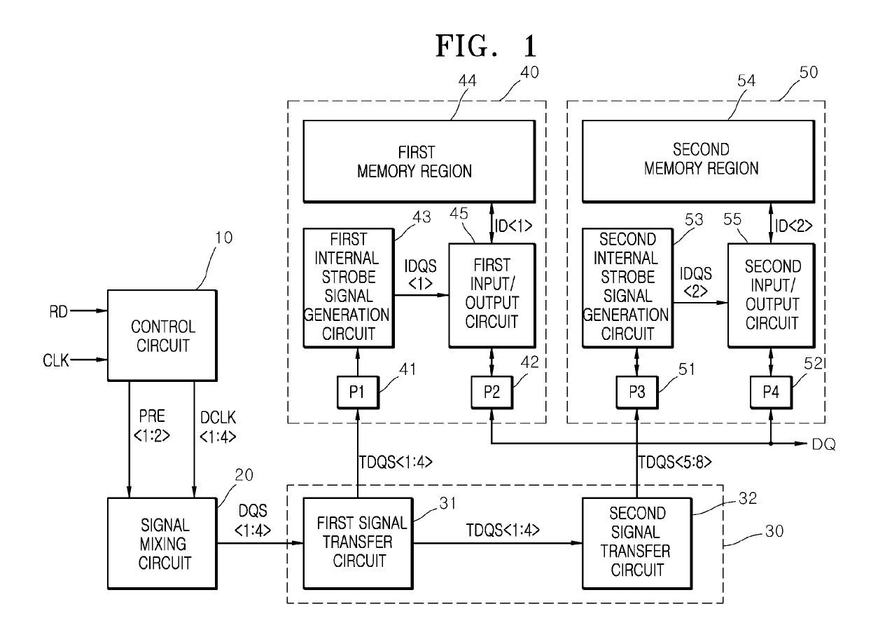

Referring to FIG. 1, a semiconductor device in accordance with an embodiment may include a control circuit 10, a signal mixing circuit 20, a signal transfer circuit 30, a first bank 40, and a second bank 50.

The control circuit 10 may generate first to fourth divided clocks DCLK<1:4> by dividing the frequency of an external clock CLK in response to a read command RD. The control circuit 10 may generate a first preamble signal PRE<1> and a second preamble signal PRE<2> which include pulses generated during a preamble period, in response to the read command RD. The first to fourth divided clocks DCLK<1:4> may be set to have a phase difference corresponding to the ¼ cycle of the external clock CLK. The pulse of the second preamble signal PRE<2> may be set to be generated after the ¼ cycle of the external clock CLK from the pulse generation time of the first preamble signal PRE<1>. The preamble period may be set as a period for the external clock CLK to be stabilized after the read command RD is inputted.

The signal mixing circuit 20 may generate first to fourth strobe signals DQS<1:4> by mixing the first to fourth divided clocks DCLK<1:4> and the first and second preamble signals PRE<1:2>. The signal mixing circuit 20 may generate the third and fourth strobe signals DQS<3:4> which toggle in synchronization with the first preamble signal PRE<1> and the second preamble signal PRE<2> during the preamble period. The signal mixing circuit 20 may generate the first to fourth strobe signals DQS<1:4> which toggle in synchronization with the first to fourth divided clocks DCLK<1:4> after the preamble period.

The signal transfer circuit 30 may include a first signal transfer circuit 31 and a second signal transfer circuit 32.

The first signal transfer circuit 31 may be realized to include at least one repeater. The first signal transfer circuit 31 may generate first to fourth transfer strobe signals TDQS<1:4> by amplifying the first to fourth strobe signals DQS<1:4> through at least one repeater. The first signal transfer circuit 31 may transmit the first to fourth transfer strobe signals TDQS<1:4> to a first pad 41. The number of repeaters included in the first signal transfer circuit 31 may be set variously depending on the length of a path through which the first to fourth strobe signals DQS<1:4> are transmitted. For example, realization may be made such that the number of repeaters included in the first signal transfer circuit 31 increases as the length of a path through which the first to fourth strobe signals DQS<1:4> are transferred is lengthened.

The second signal transfer circuit 32 may be realized to include at least one repeater. The second signal transfer circuit 32 may generate fifth to eighth transfer strobe signals TDQS<5:8> by amplifying the first to fourth transfer strobe signals TDQS<1:4> through at least one repeater. The second signal transfer circuit 32 may transmit the fifth to eighth transfer strobe signals TDQS<5:8> to a third pad 51. The number of repeaters included in the second signal transfer circuit 32 may be set variously depending on the length of a path through which the first to fourth transfer strobe signals TDQS<1:4> are transmitted. For example, realization may be made such that the number of repeaters included in the second signal transfer circuit 32 increases as the length of a path through which the first to fourth transfer strobe signals TDQS<1:4> are transferred is lengthened.

The signal transfer circuit 30 in accordance with an embodiment, configured as mentioned above, may include at least one repeater, and may amplify the first to fourth strobe signals DQS<1:4> through at least one repeater and transmit resultant signals to the first pad 41 and the third pad 51.

The first bank 40 may include the first pad 41, a second pad 42, a first internal strobe signal generation circuit 43, a first memory region 44, and a first input/output circuit 45.

The first internal strobe signal generation circuit 43 may generate a first internal strobe signal IDQS<1> by mixing the first to fourth transfer strobe signals TDQS<1:4> received from the first pad 41. An operation of generating the first internal strobe signal IDQS<1> by mixing the first to fourth transfer strobe signals TDQS<1:4> will be explained later through a configuration which will be described later.

The first memory region 44 may store first internal data ID<1> in a write operation, and may output the stored first internal data ID<1> in a read operation. The first memory region 44 may be realized by a volatile memory device or a nonvolatile memory device which includes a plurality of memory cell arrays.

The first input/output circuit 45 may input/output the first internal data ID<1> through the second pad 42 in synchronization with the first internal strobe signal IDQS<1>. The first input/output circuit 45 may output data DQ inputted through the second pad 42 in the write operation, as the first internal data ID<1>, in synchronization with the first internal strobe signal IDQS<1>. The first input/output circuit 45 may output the first internal data ID<1> as data DQ through the second pad 42 in synchronization with the first internal strobe signal IDQS<1>, in the read operation.

The first bank 40 in accordance with an embodiment, configured as mentioned above, may store the data DQ inputted through the second pad 42, as the first internal data ID<1>, in synchronization with the first to fourth transfer strobe signals TDQS<1:4> transmitted to the first pad 41, in the write operation. The first bank 40 may output the first internal data ID<1> through the second pad 42, as the data DQ, in synchronization with the first to fourth transfer strobe signals TDQS<1:4> transmitted to the first pad 41, in the read operation.

The second bank 50 may include the third pad 51, a fourth pad 52, a second internal strobe signal generation circuit 53, a second memory region 54, and a second input/output circuit 55.

The second internal strobe signal generation circuit 53 may generate a second internal strobe signal IDQS<2> by mixing the fifth to eighth transfer strobe signals TDQS<5:8> received from the third pad 51. An operation of generating the second internal strobe signal IDQS<2> by mixing the fifth to eighth transfer strobe signals TDQS<5:8> may be the same or substantially the same as the operation of generating the first internal strobe signal IDQS<1>, and thus, will be explained in later through a configuration which will be described later.

The second memory region 54 may store second internal data ID<2> in a write operation, and may output the stored second internal data ID<2> in a read operation. The second memory region 54 may be realized by a volatile memory device or a nonvolatile memory device which includes a plurality of memory cell arrays.

The second input/output circuit 55 may input/output the second internal data ID<2> through the fourth pad 52 in synchronization with the second internal strobe signal IDQS<2>. The second input/output circuit 55 may output data DQ inputted through the fourth pad 52 in the write operation, as the second internal data ID<2>, in synchronization with the second internal strobe signal IDQS<2>. The second input/output circuit 55 may output the second internal data ID<2> as data DQ through the fourth pad 52 in synchronization with the second internal strobe signal IDQS<2>, in the read operation.

The second bank 50 in accordance with an embodiment, configured as mentioned above, may store the data DQ inputted through the fourth pad 52, as the second internal data ID<2>, in synchronization with the fifth to eighth transfer strobe signals TDQS<5:8> transmitted to the third pad 51, in the write operation. The second bank 50 may output the second internal data ID<2> through the fourth pad 52, as the data DQ, in synchronization with the fifth to eighth transfer strobe signals TDQS<5:8> transmitted to the third pad 51, in the read operation.

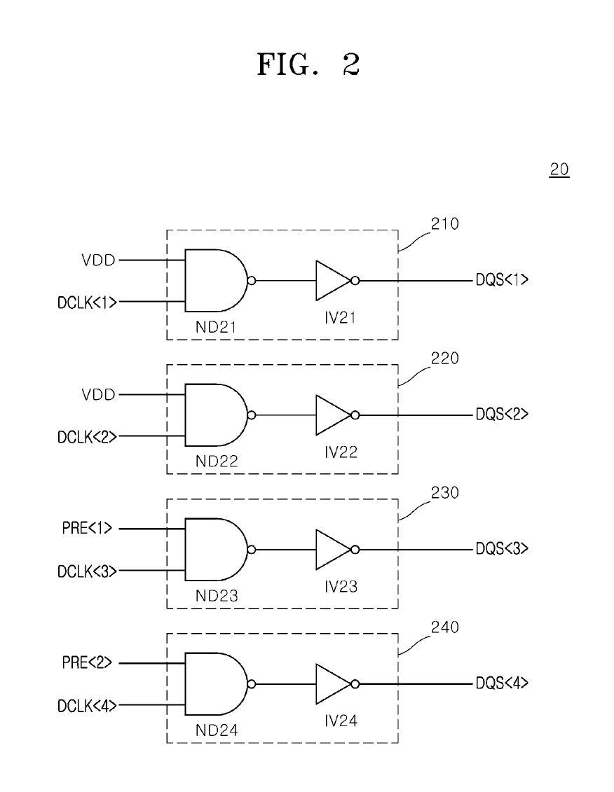

Referring to FIG. 2, the signal mixing circuit 20 in accordance with an embodiment may include a first mixing circuit 210, a second mixing circuit 220, a third mixing circuit 230, and a fourth mixing circuit 240.

The first mixing circuit 210 may be realized by a NAND gate ND21 and an inverter IV21, and may generate the first strobe signal DQS<1> by buffering the first divided clock DCLK<1> in response to a power supply voltage VDD. The first mixing circuit 210 may generate the first strobe signal DQS<1> by performing an AND logic function on the power supply voltage VDD and the first divided clock DCLK<1>. The power supply voltage VDD may be set to a logic high level.

The second mixing circuit 220 may be realized by a NAND gate ND22 and an inverter IV22, and may generate the second strobe signal DQS<2> by buffering the second divided clock DCLK<2> in response to the power supply voltage VDD. The second mixing circuit 220 may generate the second strobe signal DQS<2> by performing an AND logic function on the power supply voltage VDD and the second divided clock DCLK<2>.

The third mixing circuit 230 may be realized by a NAND gate ND23 and an inverter IV23, and may generate the third strobe signal DQS<3> by mixing the pulse of the first preamble signal PRE<1> and the pulse of the third divided clock DCLK<3>. The third mixing circuit 230 may generate the third strobe signal DQS<3> by performing an AND logic function on the first preamble signal PRE<1> and the third divided clock DCLK<3>.

The fourth mixing circuit 240 may be realized by a NAND gate ND24 and an inverter IV24, and may generate the fourth strobe signal DQS<4> by mixing the pulse of the second preamble signal PRE<2> and the pulse of the fourth divided clock DCLK<4>. The fourth mixing circuit 240 may generate the fourth strobe signal DQS<4> by performing an AND logic function on the second preamble signal PRE<2> and the fourth divided clock DCLK<4>.

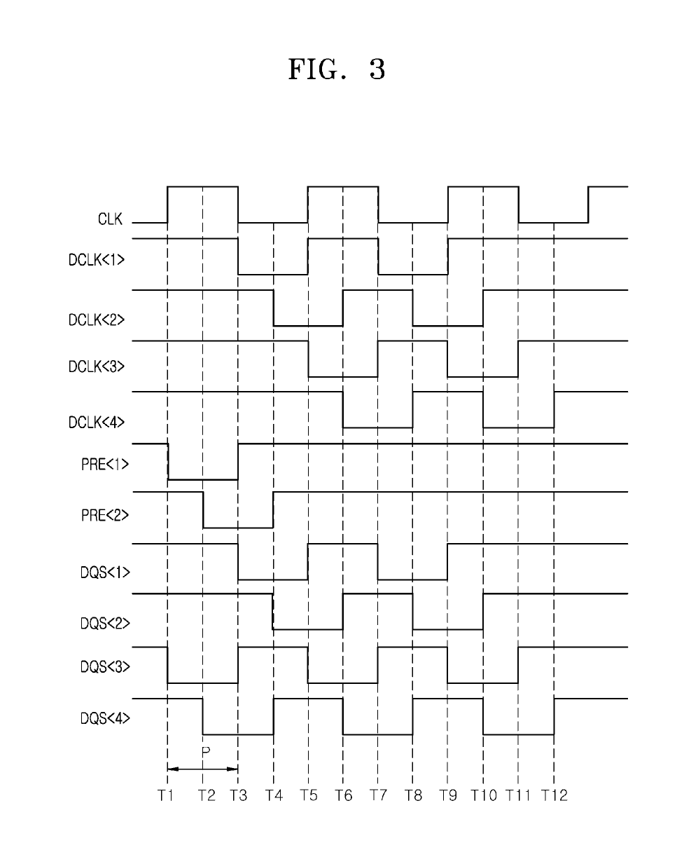

The operation of the control circuit 10 in accordance with an embodiment will be described below with reference to FIG. 3 by being divided into an operation during the preamble period and an operation after the preamble period.

Before making descriptions, a preamble period P is set to a period between times T1 and T3 as the ½ cycle of the external clock CLK. According to an embodiment, the preamble period P may be set to one or more cycles of the external clock CLK.

The control circuit 10 may generate the first preamble signal PRE<1> which includes a pulse generated between times T1 and T3 during the preamble period P.

The control circuit 10 may generate the second preamble signal PRE<2> which includes a pulse generated between times T2 and T4 during the preamble period P.

After the preamble period P, the control circuit 10 generates the first divided clock DCLK<1> which includes a first pulse between times T3 and T5 and a second pulse between times T7 and T9, by dividing the frequency of the external clock CLK.

After the preamble period P, the control circuit 10 generates the second divided clock DCLK<2> which includes a first pulse between times T4 and T6 and a second pulse between times T8 and T10, by dividing the frequency of the external clock CLK.

After the preamble period P, the control circuit 10 generates the third divided clock DCLK<3> which includes a first pulse between times T5 and T7 and a second pulse between times T9 and T11, by dividing the frequency of the external clock CLK.

After the preamble period P, the control circuit 10 generates the fourth divided clock DCLK<4> which includes a first pulse between times T6 and T8 and a second pulse between times T10 and T12, by dividing the frequency of the external clock CLK.

The pulses included in the first and second preamble signals PRE<1:2> and the first to fourth divided clocks DCLK<1:4> mean periods in which the pulses are generated at, for example but not limited to, a logic low level. Further, the logic levels of the signals may be different from or the opposite of those described. For example, a signal described as having a logic “high” level may alternatively have a logic “low” level, and a signal described as having a logic “low” level may alternatively have a logic “high” level.

In this way, the control circuit 10 in accordance with an embodiment generates the first preamble signal PRE<1> and the second preamble signal PRE<2> which include pulses generated during the preamble period. The control circuit 10 generates the pulse of the second preamble signal PRE<2> after the ¼ cycle of the external clock CLK from the pulse generation time of the first preamble signal PRE<1>. After the preamble period, the control circuit 10 generates the first to fourth divided clocks DCLK<1:4> which have the phase difference corresponding to the ¼ cycle of the external clock CLK, by dividing the frequency of the external clock CLK.

The operation of the signal mixing circuit 20 in accordance with an embodiment will be described below with reference to FIG. 3.

After the preamble period P, the first mixing circuit 210 generates the first strobe signal DQS<1> which includes a first pulse between times T3 and T5 and a second pulse between times T7 and T9, by buffering the first divided clock DCLK<1> in response to the power supply voltage VDD.

After the preamble period P, the second mixing circuit 220 generates the second strobe signal DQS<2> which includes a first pulse between times T4 and T6 and a second pulse between times T8 and T10, by buffering the second divided clock DCLK<2> in response to the power supply voltage VDD.

During the preamble period P, the third mixing circuit 230 generates the first pulse of the third strobe signal DQS<3> between times T1 and T3, by mixing the pulse of the first preamble signal PRE<1> and the third divided clock DCLK<3>. After the preamble period P, the third mixing circuit 230 generates the second pulse of the third strobe signal DQS<3> between times T5 and T7, by mixing the first preamble signal PRE<1> and the first pulse of the third divided clock DCLK<3>. After the preamble period P, the third mixing circuit 230 generates the third pulse of the third strobe signal DQS<3> between times T9 and T11, by mixing the first preamble signal PRE<1> and the second pulse of the third divided clock DCLK<3>.

During the preamble period P, the fourth mixing circuit 240 generates the first pulse of the fourth strobe signal DQS<4> between times T2 and T4, by mixing the pulse of the second preamble signal PRE<2> and the fourth divided clock DCLK<4>. After the preamble period P, the fourth mixing circuit 240 generates the second pulse of the fourth strobe signal DQS<4> between times T6 and T8, by mixing the second preamble signal PRE<2> and the first pulse of the fourth divided clock DCLK<4>. After the preamble period P, the fourth mixing circuit 240 generates the third pulse of the fourth strobe signal DQS<4> between times T10 and T12, by mixing the second preamble signal PRE<2> and the second pulse of the fourth divided clock DCLK<4>.

The pulses included in the first to fourth strobe signals DQS<1:4> mean periods in which the pulses are generated at, for example but not limited to, a logic low level. Further, the logic levels of the signals may be different from or the opposite of those described. For example, a signal described as having a logic “high” level may alternatively have a logic “low” level, and a signal described as having a logic “low” level may alternatively have a logic “high” level.

In this way, the signal mixing circuit 20 in accordance with an embodiment generates the first to fourth strobe signals DQS<1:4> by mixing the first to fourth divided clocks DCLK<1:4> and the first and second preamble signals PRE<1:2>. The signal mixing circuit 20 generates the third and fourth strobe signals DQS<3:4> which toggle in synchronization with the first preamble signal PRE<1> and the second preamble signal PRE<2> during the preamble period. The signal mixing circuit 20 generates the first to fourth strobe signals DQS<1:4> which toggle in synchronization with the first to fourth divided clocks DCLK<1:4> after the preamble period.

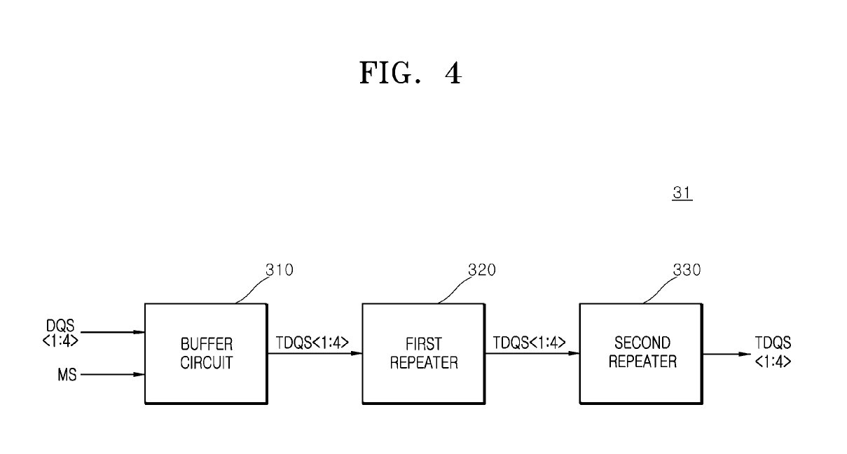

Referring to FIG. 4, the first signal transfer circuit 31 in accordance with an embodiment may include a buffer circuit 310, a first repeater 320, and a second repeater 330.

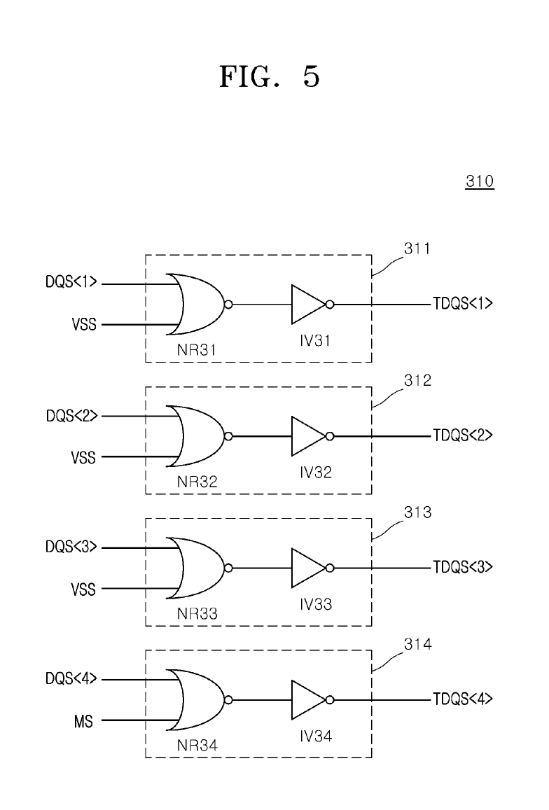

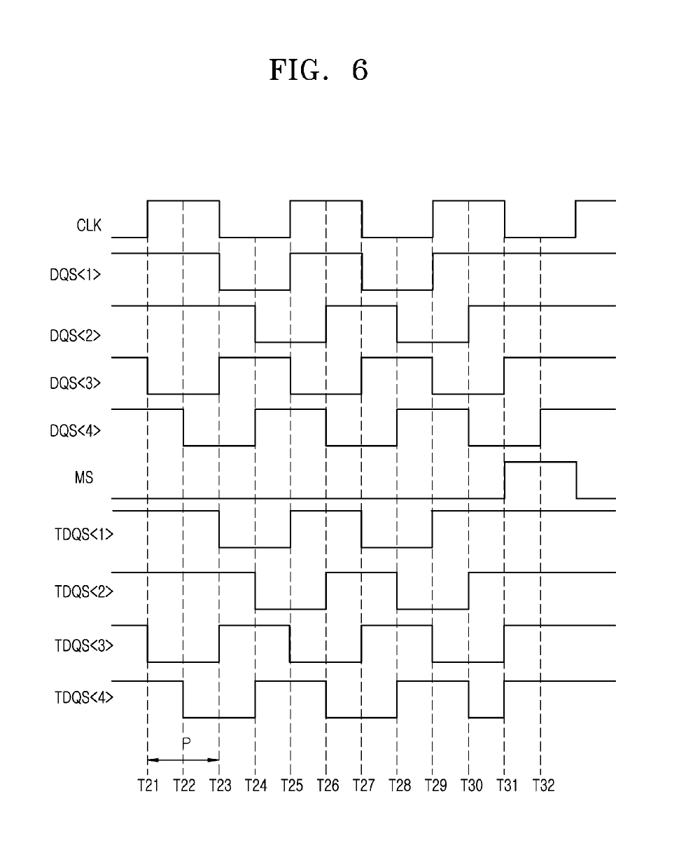

The buffer circuit 310 may generate the first to fourth transfer strobe signals TDQS<1:4> by buffering the first to fourth strobe signals DQS<1:4>. The internal configuration of the buffer circuit 310 will be described later with reference to FIG. 5. The buffer circuit 310 may adjust the pulse width of the last pulse of the fourth transfer strobe signal TDQS<4> in response to a masking signal MS. The masking signal MS is a signal which is inputted from an exterior to adjust the pulse width of the last pulse of the fourth transfer strobe signal TDQS<4> depending on the burst length of data DQ. An operation of adjusting the pulse width of the last pulse of the fourth transfer strobe signal TDQS<4> will be described later with reference to FIGS. 5 and 6.

The first repeater 320 may amplify and output the first to fourth transfer strobe signals TDQS<1:4>. The first repeater 320 may be realized by an inverter and a driver which are generally known in the art, and may amplify and output the first to fourth transfer strobe signals TDQS<1:4>.

The second repeater 330 may amplify and output the first to fourth transfer strobe signals TDQS<1:4> outputted from the first repeater 320. The second repeater 330 may amplify the first to fourth transfer strobe signals TDQS<1:4> and transmit them to the first pad 41. The second repeater 330 may be realized by an inverter and a driver which are generally known in the art, and may amplify and output the first to fourth transfer strobe signals TDQS<1:4>.

The first signal transfer circuit 31 in accordance with an embodiment, configured as mentioned above, may generate the first to fourth transfer strobe signals TDQS<1:4> by amplifying the first to fourth strobe signals DQS<1:4> through the first repeater 320 and the second repeater 330. The first signal transfer circuit 31 may output the first to fourth transfer strobe signals TDQS<1:4> to the first pad 41.

The second signal transfer circuit 32 illustrated in FIG. 1 may be realized to include repeaters the same as the first repeater 320 and the second repeater 330 illustrated in FIG. 4, and may generate the fifth to eighth transfer strobe signals TDQS<5:8> by amplifying the first to fourth transfer strobe signals TDQS<1:4>. The second signal transfer circuit 32 may transmit the amplified fifth to eighth transfer strobe signals TDQS<5:8> to the third pad 51.

Referring to FIG. 5, the buffer circuit 310 in accordance with an embodiment may include a first logic circuit 311, a second logic circuit 312, a third logic circuit 313, and a fourth logic circuit 314.

The first logic circuit 311 may be realized by a NOR gate NR31 and an inverter IV31, and may generate the first transfer strobe signal TDQS<1> by buffering the first strobe signal DQS<1> in response to a ground voltage VSS. The first logic circuit 311 may generate the first transfer strobe signal TDQS<1> by performing an OR logic function on the ground voltage VSS and the first strobe signal DQS<1>.

The second logic circuit 312 may be realized by a NOR gate NR32 and an inverter IV32, and may generate the second transfer strobe signal TDQS<2> by buffering the second strobe signal DQS<2> in response to the ground voltage VSS. The second logic circuit 312 may generate the second transfer strobe signal TDQS<2> by performing an OR logic function on the ground voltage VSS and the second strobe signal DQS<2>.

The third logic circuit 313 may be realized by a NOR gate NR33 and an inverter IV33, and may generate the third transfer strobe signal TDQS<3> by buffering the third strobe signal DQS<3> in response to the ground voltage VSS. The third logic circuit 313 may generate the third transfer strobe signal TDQS<3> by performing an OR logic function on the ground voltage VSS and the third strobe signal DQS<3>.

The fourth logic circuit 314 may be realized by a NOR gate NR34 and an inverter IV34, and may generate the fourth transfer strobe signal TDQS<4> by buffering the fourth strobe signal DQS<4> in response to the masking signal MS. The fourth logic circuit 314 may generate the fourth transfer strobe signal TDQS<4> by performing an OR logic function on the masking signal MS and the fourth strobe signal DQS<4>. The fourth logic circuit 314 generates the fourth transfer strobe signal TDQS<4> of a logic high level at a time when the masking signal MS is inputted.

The buffer circuit 310 in accordance with an embodiment, configured as mentioned above, may generate the first to fourth transfer strobe signals TDQS<1:4> by buffering the first to fourth strobe signals DQS<1:4>. The buffer circuit 310 may adjust the pulse width of the last pulse of the fourth transfer strobe signal TDQS<4> in response to the masking signal MS.

The operation of the buffer circuit 310 in accordance with an embodiment will be described below with reference to FIG. 6 by being divided into an operation during the preamble period and an operation after the preamble period.

Before making descriptions, a preamble period P is set to a period between times T21 and T23 as the ½ cycle of the external clock CLK. According to an embodiment, the preamble period P may be set to one or more cycles of the external clock CLK. Also, times T21 to T32 illustrated in FIG. 6 may be set as times the same as times T1 to T12 illustrated in FIG. 3.

The first logic circuit 311 generates the first transfer strobe signal TDQS<1> of a logic high level by buffering the first strobe signal DQS<1> in response to the ground voltage VSS between times T21 and T23 as the preamble period P. The first logic circuit 311 generates the first pulse of the first transfer strobe signal TDQS<1> between times T23 and T25 by buffering the first strobe signal DQS<1> in response to the ground voltage VSS between times T23 and T25 after the preamble period P. The first logic circuit 311 generates the second pulse of the first transfer strobe signal TDQS<1> between times T27 and T29 by buffering the first strobe signal DQS<1> in response to the ground voltage VSS between times T27 and T29 after the preamble period P.

The second logic circuit 312 generates the second transfer strobe signal TDQS<2> of a logic high level by buffering the second strobe signal DQS<2> in response to the ground voltage VSS between times T21 and T23 as the preamble period P. The second logic circuit 312 generates the first pulse of the second transfer strobe signal TDQS<2> between times T24 and T26 by buffering the second strobe signal DQS<2> in response to the ground voltage VSS between times T24 and T26 after the preamble period P. The second logic circuit 312 generates the second pulse of the second transfer strobe signal TDQS<2> between times T28 and T30 by buffering the second strobe signal DQS<2> in response to the ground voltage VSS between times T28 and T30 after the preamble period P.

The third logic circuit 313 generates the first pulse of the third transfer strobe signal TDQS<3> between times T21 and T23 by buffering the third strobe signal DQS<3> in response to the ground voltage VSS between times T21 and T23 as the preamble period P. The third logic circuit 313 generates the second pulse of the third transfer strobe signal TDQS<3> between times T25 and T27 by buffering the third strobe signal DQS<3> in response to the ground voltage VSS between times T25 and T27 after the preamble period P. The third logic circuit 313 generates the third pulse of the third transfer strobe signal TDQS<3> between times T29 and T31 by buffering the third strobe signal DQS<3> in response to the ground voltage VSS between times T29 and T31 after the preamble period P.

The fourth logic circuit 314 generates the first pulse of the fourth transfer strobe signal TDQS<4> between times T22 and T24 by buffering the fourth strobe signal DQS<4> in response to the masking signal MS between times T21 and T23 as the preamble period P. The fourth logic circuit 314 generates the second pulse of the fourth transfer strobe signal TDQS<4> between times T26 and T28 by buffering the fourth strobe signal DQS<4> in response to the masking signal MS between times T26 and T28 after the preamble period P. The fourth logic circuit 314 generates the third pulse of the fourth transfer strobe signal TDQS<4> between times T30 and T31 by buffering the fourth strobe signal DQS<4> in response to the masking signal MS between times T30 and T31 after the preamble period P. The masking signal MS is inputted at time T31, and adjusts the pulse width of the last pulse of the fourth transfer strobe signal TDQS<4>.

The pulses included in the first to fourth transfer strobe signals TDQS<1:4> mean the periods in which the pulses are generated at, for example but not limited to, a logic low level.

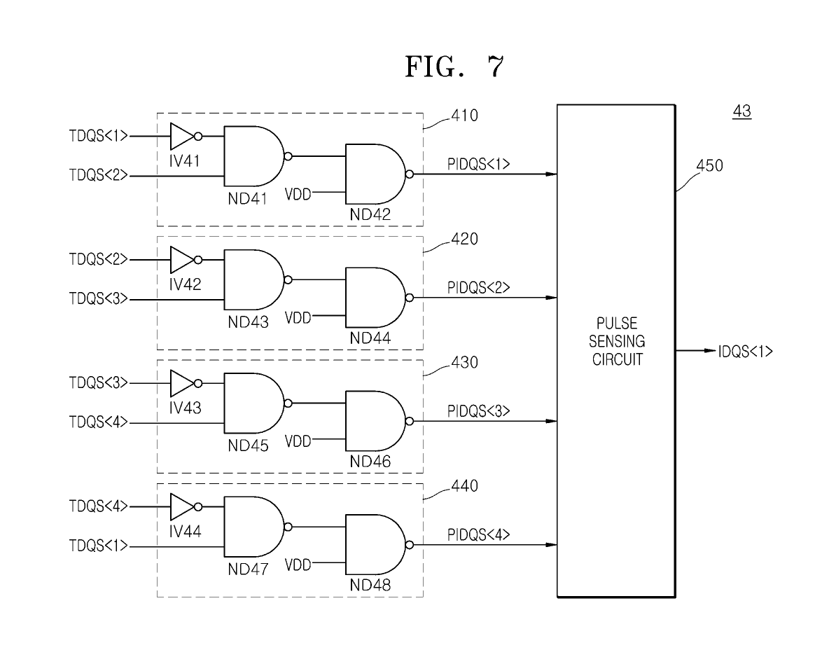

Referring to FIG. 7, the first internal strobe signal generation circuit 43 in accordance with an embodiment may include a fifth logic circuit 410, a sixth logic circuit 420, a seventh logic circuit 430, an eighth logic circuit 440, and a pulse sensing circuit 450.

The fifth logic circuit 410 may be realized by an inverter IV41 and NAND gates ND41 and ND42, and may generate a first pre-internal strobe signal PIDQS<1> by buffering the second transfer strobe signal TDQS<2> during a period in which the pulse of the first transfer strobe signal TDQS<1> is generated. The fifth logic circuit 410 may generate the first pre-internal strobe signal PIDQS<1> of a logic low level during a period in which the pulse of the first transfer strobe signal TDQS<1> is not generated.

The sixth logic circuit 420 may be realized by an inverter IV42 and NAND gates ND43 and ND44, and may generate a second pre-internal strobe signal PIDQS<2> by buffering the third transfer strobe signal TDQS<3> during a period in which the pulse of the second transfer strobe signal TDQS<2> is generated. The sixth logic circuit 420 may generate the second pre-internal strobe signal PIDQS<2> of a logic low level during a period in which the pulse of the second transfer strobe signal TDQS<2> is not generated.

The seventh logic circuit 430 may be realized by an inverter IV43 and NAND gates ND45 and ND46, and may generate a third pre-internal strobe signal PIDQS<3> by buffering the fourth transfer strobe signal TDQS<4> during a period in which the pulse of the third transfer strobe signal TDQS<3> is generated. The seventh logic circuit 430 may generate the third pre-internal strobe signal PIDQS<3> of a logic low level during a period in which the pulse of the third transfer strobe signal TDQS<3> is not generated.

The eighth logic circuit 440 may be realized by an inverter IV44 and NAND gates ND47 and ND48, and may generate a fourth pre-internal strobe signal PIDQS<4> by buffering the first transfer strobe signal TDQS<1> during a period in which the pulse of the fourth transfer strobe signal TDQS<4> is generated. The eighth logic circuit 440 may generate the fourth pre-internal strobe signal PIDQS<4> of a logic low level during a period in which the pulse of the fourth transfer strobe signal TDQS<4> is not generated.

The pulse sensing circuit 450 may generate the first internal strobe signal IDQS<1> which transitions in its level at a time when any one among the pulses included in the first to fourth pre-internal strobe signals PIDQS<1:4> is inputted.

The first internal strobe signal generation circuit 43 in accordance with an embodiment, configured as mentioned above, may generate the first internal strobe signal IDQS<1> by mixing the first to fourth transfer strobe signals TDQS<1:4> received from the first pad 41.

The second internal strobe signal generation circuit 53 illustrated in FIG. 1 may be realized by a circuit the same as or substantially the same as the first internal strobe signal generation circuit 43 illustrated in FIG. 7 except that signals inputted thereto and outputted therefrom are different.

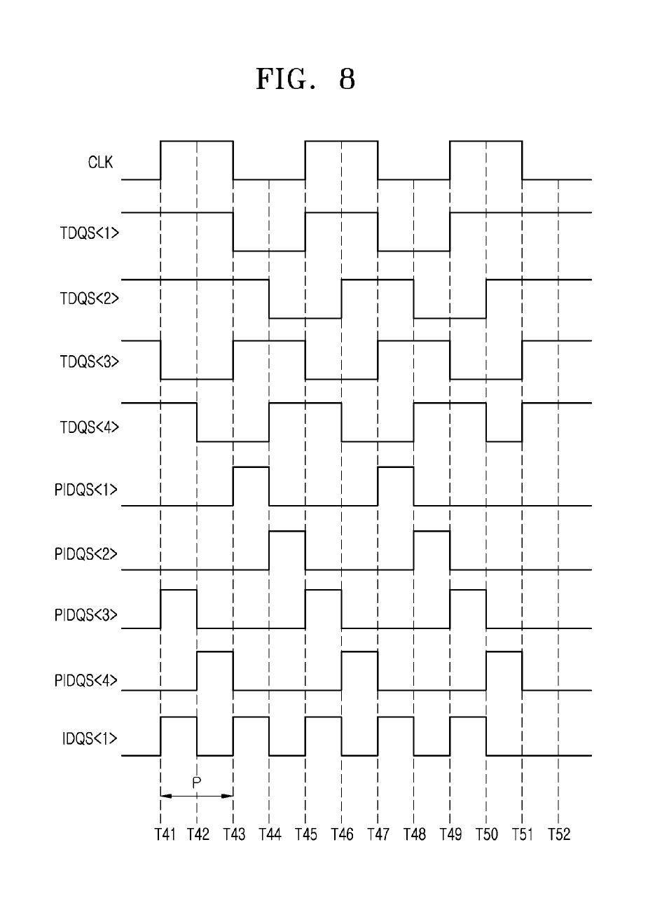

The operation of the first internal strobe signal generation circuit 43 in accordance with the embodiment will be described below with reference to FIG. 8 by being divided into an operation during the preamble period and an operation after the preamble period.

Before making descriptions, a preamble period P is set to a period between times T41 and T43 as the ½ cycle of the external clock CLK. According to an embodiment, the preamble period P may be set to one or more cycles of the external clock CLK. Also, times T41 to T52 illustrated in FIG. 8 may be set, for example but not limited to, as times the same as times T1 to T12 illustrated in FIG. 3 and times T21 to T32 illustrated in FIG. 6.

The fifth logic circuit 410 generates the first pre-internal strobe signal PIDQS<1> of the logic low level during the period in which the pulse of the first transfer strobe signal TDQS<1> is not generated, between times T41 and T43 as the preamble period P. The fifth logic circuit 410 generates the first pulse of the first pre-internal strobe signal PIDQS<1> between times T43 and T44 by buffering the second transfer strobe signal TDQS<2> during the period in which the pulse of the first transfer strobe signal TDQS<1> is generated, between times T43 and T45 after the preamble period P. The fifth logic circuit 410 generates the second pulse of the first pre-internal strobe signal PIDQS<1> between times T47 and T48 by buffering the second transfer strobe signal TDQS<2> during the period in which the pulse of the first transfer strobe signal TDQS<1> is generated, between times T47 and T49 after the preamble period P.

The sixth logic circuit 420 generates the second pre-internal strobe signal PIDQS<1> of the logic low level during the period in which the pulse of the second transfer strobe signal TDQS<2> is not generated, between times T41 and T43 as the preamble period P. The sixth logic circuit 420 generates the first pulse of the second pre-internal strobe signal PIDQS<2> between times T44 and T45 by buffering the third transfer strobe signal TDQS<3> during the period in which the pulse of the second transfer strobe signal TDQS<2> is generated, between times T44 and T46 after the preamble period P. The sixth logic circuit 420 generates the second pulse of the second pre-internal strobe signal PIDQS<2> between times T48 and T49 by buffering the third transfer strobe signal TDQS<3> during the period in which the pulse of the second transfer strobe signal TDQS<2> is generated, between times T48 and T50 after the preamble period P.

The seventh logic circuit 430 generates the first pulse of the third pre-internal strobe signal PIDQS<3> between times T41 and T42 by buffering the fourth transfer strobe signal TDQS<4> during the period in which the pulse of the third transfer strobe signal TDQS<3> is generated, between times T41 and T43 as the preamble period P. The seventh logic circuit 430 generates the second pulse of the third pre-internal strobe signal PIDQS<3> between times T45 and T46 by buffering the fourth transfer strobe signal TDQS<4> during the period in which the pulse of the third transfer strobe signal TDQS<3> is generated, between times T45 and T47 after the preamble period P. The seventh logic circuit 430 generates the third pulse of the third pre-internal strobe signal PIDQS<3> between times T49 and T50 by buffering the fourth transfer strobe signal TDQS<4> during the period in which the pulse of the third transfer strobe signal TDQS<3> is generated, between times T49 and T51 after the preamble period P.

The eighth logic circuit 440 generates the first pulse of the fourth pre-internal strobe signal PIDQS<4> between times T42 and T43 by buffering the first transfer strobe signal TDQS<1> during the period in which the pulse of the fourth transfer strobe signal TDQS<4> is generated, between times T41 and T43 as the preamble period P. The eighth logic circuit 440 generates the second pulse of the fourth pre-internal strobe signal PIDQS<4> between times T46 and T47 by buffering the first transfer strobe signal TDQS<1> during the period in which the pulse of the fourth transfer strobe signal TDQS<4> is generated, between times T46 and T48 after the preamble period P. The eighth logic circuit 440 generates the fourth pre-internal strobe signal PIDQS<4> of a logic high level between times T50 and T51 by buffering the first transfer strobe signal TDQS<1> during the period in which the pulse of the fourth transfer strobe signal TDQS<4> is generated, between times T50 and T51 after the preamble period P.

The pulses included in the first to fourth pre-internal transfer strobe signals PIDQS<1:4> mean periods in which the pulses are generated at, for example but not limited to, a logic high level.

The pulse sensing circuit 450 generates the first internal strobe signal IDQS<1> which transitions in its level in response to the pulses of the third and fourth pre-internal strobe signals PIDQS<3:4>, between times T41 and T43 as the preamble period P. The pulse sensing circuit 450 generates the first internal strobe signal IDQS<1> which transitions in its level in response to the pulses of the first to fourth pre-internal strobe signals PIDQS<1:4>, between times T43 and T50 after the preamble period P.

The operation of the semiconductor device in accordance with an embodiment will be described with reference to FIGS. 1 to 8 by providing, for example, a read operation for the first bank 40.

The control circuit 10 generates the first preamble signal PRE<1> and the second preamble signal PRE<2> which include pulses generated during the preamble period, in response to the read command RD. The control circuit 10 generates the first to fourth divided clocks DCLK<1:4> by dividing the frequency of the external clock CLK in response to the read command RD.

The signal mixing circuit 20 generates the third and fourth strobe signals DQS<3:4> which toggle in synchronization with the first preamble signal PRE<1> and the second preamble signal PRE<2> during the preamble period. The signal mixing circuit 20 generates the first to fourth strobe signals DQS<1:4> which toggle in synchronization with the first to fourth divided clocks DCLK<1:4> after the preamble period.

The buffer circuit 310 of the first signal transfer circuit 31 generates the first to fourth transfer strobe signals TDQS<1:4> by buffering the first to fourth strobe signals DQS<1:4>. The first repeater 320 amplifies and outputs the first to fourth transfer strobe signals TDQS<1:4>. The second repeater 330 amplifies the first to fourth transfer strobe signals TDQS<1:4> outputted from the first repeater 320, and transmits the first to fourth transfer strobe signals TDQS<1:4> to the first pad 41.

The first internal strobe signal generation circuit 43 generates the first internal strobe signal IDQS<1> which toggles, by mixing the first to fourth transfer strobe signals TDQS<1:4> transmitted to the first pad 41 during the preamble period and after the preamble period.

The first memory region 44 outputs the first internal data ID<1> stored therein.

The first input/output circuit 45 outputs the first internal data ID<1> through the second pad 42 in synchronization with the rising edge and falling edge of the first internal strobe signal IDQS<1>.

As is apparent from the above descriptions, in a semiconductor device according to an embodiment, a strobe signal is generated by mixing a divided clock and a preamble signal during a preamble period, and the strobe signal is outputted through a plurality of repeaters to a pad. As a consequence, it may be possible to prevent a mismatch of the divided clock and the preamble signal due to a long transfer path.

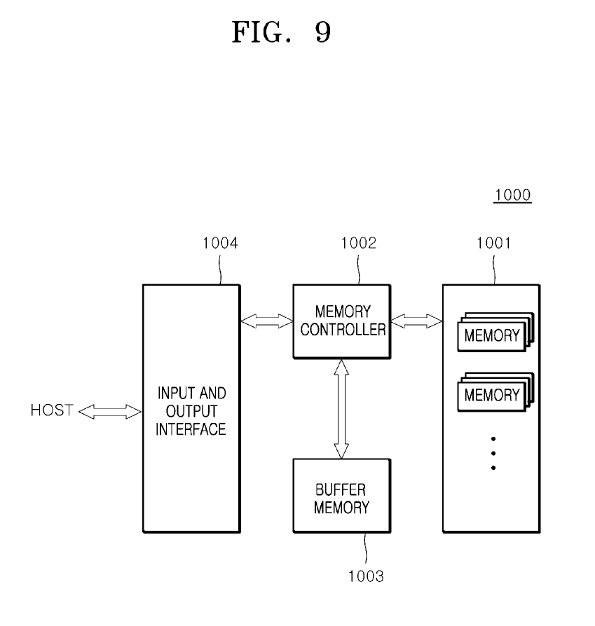

The semiconductor devices described above with reference to FIGS. 1 to 8 may be applied to an electronic system which includes a memory system, a graphic system, a computing system or a mobile system. For example, referring to FIG. 9, an electronic system 1000 in accordance with an embodiment may include a data storage 1001, a memory controller 1002, a buffer memory 1003, and an input/output interface 1004.

The data storage 1001 stores data applied from the memory controller 1002, and reads out stored data and outputs the read-out data to the memory controller 1002, according to control signals from the memory controller 1002. The data storage 1001 may include the semiconductor devices illustrated in FIG. 1. The data storage 1001 may include a nonvolatile memory capable of not losing and continuously storing data even though power supply is interrupted. A nonvolatile memory may be realized as a flash memory such as a NOR flash memory and a NAND flash memory, a phase change random access memory (PRAM), a resistive random access memory (RRAM), a spin transfer torque random access memory (STTRAM) or a magnetic random access memory (MRAM).

The memory controller 1002 decodes commands applied through the input/output interface 1004 from an external device (a host), and controls input/output of data with respect to the data storage 1001 and the buffer memory 1003 according to decoding results. While the memory controller 1002 is illustrated as one block in FIG. 9, it is to be noted that, in the memory controller 1002, a controller for controlling a nonvolatile memory and a controller for controlling the buffer memory 1003 as a volatile memory may be independently configured.

The buffer memory 1003 may temporarily store data to be processed in the memory controller 1002, that is, data to be inputted and outputted to and from the data storage 1001. The buffer memory 1003 may store data applied from the memory controller 1002 according to a control signal. The buffer memory 1003 reads out stored data and outputs the read-out data to the memory controller 1002. The buffer memory 1003 may include a volatile memory such as a DRAM (dynamic random access memory), a mobile DRAM and an SRAM (static random access memory).

The input/output interface 1004 provides a physical coupling between the memory controller 1002 and the external device (the host) such that the memory controller 1002 may receive control signals for input/output of data from the external device and exchange data with the external device. The input/output interface 1004 may include one among various interface protocols such as USB, MMC, PCI-E, SAS, SATA, PATA, SCSI, ESDI and IDE.

The electronic system 1000 may be used as an auxiliary memory device or an external storage device of the host. The electronic system 1000 may include a solid state disk (SSD), a USB memory (universal serial bus memory), a secure digital (SD) card, a mini-secure digital (mSD) card, a micro SD card, a secure digital high capacity (SDHC) card, a memory stick card, a smart media (SM) card, a multimedia card (MMC), an embedded MMC (eMMC), or a compact flash (CF) card.

While various embodiments have been described above, it will be understood to those skilled in the art that the embodiments described are by way of example only. Accordingly, the semiconductor device described herein should not be limited based on the described embodiments.

1. A semiconductor device comprising:
a signal mixing circuit suitable for generating a strobe signal which toggles in synchronization with a divided clock after a preamble period; and
a signal transfer circuit suitable for transmitting the strobe signal to a pad, and including at least one repeater which amplifies and transmits the strobe signal.

2. The semiconductor device according to claim 1, wherein the strobe signal is a signal which toggles in synchronization with a preamble signal during the preamble period.

3. The semiconductor device according to claim 1, wherein the signal mixing circuit comprises:
a first mixing circuit suitable for generating a first strobe signal by buffering a first divided clock based on a power supply voltage;
a second mixing circuit suitable for generating a second strobe signal by buffering a second divided clock based on the power supply voltage;
a third mixing circuit suitable for generating a third strobe signal by mixing a pulse of a first preamble signal and a pulse of a third divided clock; and
a fourth mixing circuit suitable for generating a fourth strobe signal by mixing a pulse of a second preamble signal and a pulse of a fourth divided clock.

4. The semiconductor device according to claim 3, further comprising:
a control circuit suitable for generating the first to fourth divided clocks which have a phase difference corresponding to ¼ cycle of an external clock, by dividing a frequency of the external clock based on a read command, and generating the first and second preamble signals which include pulses generated during the preamble period.

5. The semiconductor device according to claim 4, wherein the pulse of the second preamble signal is generated after ¼ cycle of the external clock from a pulse generation time of the first preamble signal.

6. The semiconductor device according to claim 3, wherein the signal transfer circuit comprises:
a buffer circuit suitable for generating first to fourth transfer strobe signals by buffering the first to fourth strobe signals;
a first repeater suitable for amplifying and transmitting the first to fourth transfer strobe signals; and
a second repeater suitable for amplifying the first to fourth transfer strobe signals outputted from the first repeater, and transmitting the first to fourth transfer strobe signals to the pad.

7. The semiconductor device according to claim 6, wherein the buffer circuit comprises:
a first logic circuit suitable for generating the first transfer strobe signal by buffering the first strobe signal based on a ground voltage;
a second logic circuit suitable for generating the second transfer strobe signal by buffering the second strobe signal based on the ground voltage;
a third logic circuit suitable for generating the third transfer strobe signal by buffering the third strobe signal based on the ground voltage; and
a fourth logic circuit suitable for generating the fourth transfer strobe signal by buffering the fourth strobe signal based on a masking signal.

8. The semiconductor device according to claim 6, further comprising:
a bank suitable for inputting and outputting (inputting/outputting) internal data in synchronization with the first to fourth transfer strobe signals transmitted to the pad.

9. The semiconductor device according to claim 8, wherein the bank comprises:
an internal strobe signal generation circuit suitable for generating an internal strobe signal by mixing the first to fourth transfer strobe signals received from the pad;
a memory region suitable for storing the internal data in a write operation, and outputting the internal data in a read operation; and
an input and output (input/output) circuit suitable for inputting/outputting the internal data in synchronization with the internal strobe signal.

10. The semiconductor device according to claim 9, wherein the internal strobe signal generation circuit comprises:
a fifth logic circuit suitable for generating a first pre-internal strobe signal by buffering the second transfer strobe signal during a period in which a pulse of the first transfer strobe signal is generated;
a sixth logic circuit suitable for generating a second pre-internal strobe signal by buffering the third transfer strobe signal during a period in which a pulse of the second transfer strobe signal is generated;
a seventh logic circuit suitable for generating a third pre-internal strobe signal by buffering the fourth transfer strobe signal during a period in which a pulse of the third transfer strobe signal is generated;
an eighth logic circuit suitable for generating a fourth pre-internal strobe signal by buffering the first transfer strobe signal during a period in which a pulse of the fourth transfer strobe signal is generated; and
a pulse sensing circuit suitable for generating the internal strobe signal which transitions in its level at a time when any one of pulses included in the first to fourth pre-internal strobe signals is inputted.

11. A semiconductor device comprising:
a signal mixing circuit suitable for generating a strobe signal which toggles in synchronization with a divided clock after a preamble period; and
a signal transfer circuit suitable for transmitting the strobe signal to a first pad and a second pad, and including at least one repeater which amplifies and transmits the strobe signal.

12. The semiconductor device according to claim 11, wherein the strobe signal is a signal which toggles in synchronization with a preamble signal during the preamble period.

13. The semiconductor device according to claim 11, wherein the signal mixing circuit comprises:
a first mixing circuit suitable for generating a first strobe signal by buffering a first divided clock based on a power supply voltage;
a second mixing circuit suitable for generating a second strobe signal by buffering a second divided clock based on the power supply voltage;
a third mixing circuit suitable for generating a third strobe signal by mixing a pulse of a first preamble signal and a pulse of a third divided clock; and
a fourth mixing circuit suitable for generating a fourth strobe signal by mixing a pulse of a second preamble signal and a pulse of a fourth divided clock.

14. The semiconductor device according to claim 13, further comprising:
a control circuit suitable for generating the first to fourth divided clocks which have a phase difference corresponding to ¼ cycle of an external clock, by dividing a frequency of the external clock in response to a read command, and generating the first and second preamble signals which include pulses generated during the preamble period.

15. The semiconductor device according to claim 14, wherein the pulse of the second preamble signal is generated after ¼ cycle of the external clock from a pulse generation time of the first preamble signal.

16. The semiconductor device according to claim 13, wherein the signal transfer circuit comprises:
a first signal transfer circuit suitable for generating first to fourth transfer strobe signals by buffering the first to fourth strobe signals, and amplifying the first to fourth transfer strobe signals and transmitting the first to fourth transfer strobe signals to the first pad; and
a second signal transfer circuit suitable for generating fifth to eighth transfer strobe signals by amplifying the first to fourth transfer strobe signals, and transmitting the fifth to eighth transfer strobe signals to the second pad.

17. The semiconductor device according to claim 16, wherein the first signal transfer circuit comprises:
a buffer circuit suitable for generating first to fourth transfer strobe signals by buffering the first to fourth strobe signals;
a first repeater suitable for amplifying and transmitting the first to fourth transfer strobe signals; and
a second repeater suitable for amplifying the first to fourth transfer strobe signals outputted from the first repeater, and transmitting the first to fourth transfer strobe signals to the first pad.

18. The semiconductor device according to claim 17, wherein the buffer circuit comprises:
a first logic circuit suitable for generating the first transfer strobe signal by buffering the first strobe signal based on a ground voltage;
a second logic circuit suitable for generating the second transfer strobe signal by buffering the second strobe signal based on the ground voltage;
a third logic circuit suitable for generating the third transfer strobe signal by buffering the third strobe signal based on the ground voltage; and
a fourth logic circuit suitable for generating the fourth transfer strobe signal by buffering the fourth strobe signal based on a masking signal.

19. The semiconductor device according to claim 16, wherein the second signal transfer circuit comprises:
a third repeater suitable for amplifying and transmitting the first to fourth transfer strobe signals; and
a fourth repeater suitable for amplifying the first to fourth transfer strobe signals outputted from the third repeater, and transmitting the first to fourth transfer strobe signals to the second pad.

20. The semiconductor device according to claim 16, further comprising:
a first bank suitable for inputting and outputting (inputting/outputting) first internal data in synchronization with the first to fourth transfer strobe signals transmitted to the first pad; and
a second bank suitable for inputting/outputting second internal data in synchronization with the fifth to eighth transfer strobe signals transmitted to the second pad.
